(19) United States
(12) Patent Application Publication
(10) Pub. No.: US 2025/0353292 A1
(43) Pub. Date: Nov. 20, 2025

(54) SCREEN MASK FOR SCREEN PRINTING AND MANUFACTURING METHOD OF THE SAME

(71) Applicant: SAMSUNG DISPLAY CO., LTD., Yongin-si (KR)

(72) Inventors: HYUNHO JEONG, Yongin-si (KR); Dong Ho KIM, Yongin-si (KR); Ju Suk OH, Yongin-si (KR)

(21) Appl. No.: 18/972,489

(22) Filed: Dec. 6, 2024

(30) Foreign Application Priority Data
May 16, 2024 (KR) 10-2024-0063793

(51) Int. Cl. B41F 15/36; G03F 7/12; G03F 7/20

(52) U.S. Cl. CPC B41F 15/36; G03F 7/12; G03F 7/2045

(57) ABSTRACT

A screen mask for screen printing and a manufacturing method of the same are disclosed. A screen mask includes a mesh, a first mask layer having a first thickness and located in a first region of the mesh, a second mask layer having a second thickness and located in a second region of the mesh, and the first mask layer has an opening adjacent to a boundary of the second mask layer.

### CROSS-REFERENCE TO RELATED APPLICATION

The present application claims priority to and the benefit of Korean Patent Application No. 10-2024-0063793, filed on May 16, 2024 in the Korean Intellectual Property Office, the entire disclosure of which is incorporated herein by reference.

### BACKGROUND

### 1. Field

Aspects of embodiments of the present disclosure relate to a screen mask for screen printing and a manufacturing method of the same.

### 2. Description of the Related Art

A display device such as a light emitting display or a liquid crystal display may be used for electronic devices, such as smartphones, mobile phones, and multimedia terminals. Since a display device, particularly a screen of a display device, is a part exposed from the electronic device to the outside, the display device is a key element in a design of the electronic device. For example, a cover glass, which is disposed on the outside of the display device to protect the display device and is exposed to the outside, has a great influence on the design of the electronic device.

A cover glass may have a printed bezel part to cover peripheral areas other than the screen. A screen-printing method is generally used to print the bezel part. However, when the bezel part is printed using the screen-printing method, various defects such as thread-type defects, black spot defects, and white spot defects may occur due to unwanted ink on the screen when the ink is pushed out, such as by using a squeegee.

### SUMMARY

According to an aspect of embodiments of the present disclosure, defects caused by smudges on a screen when screen printing is used to form a bezel part of a cover glass may be prevented (prevented or substantially prevented).

According to one or more embodiments, a screen mask includes a mesh, a first mask layer having a first thickness and located in a first region of the mesh, a second mask layer having a second thickness and located in a second region of the mesh, and the first mask layer has an opening adjacent to a boundary of the second mask layer. The opening may be formed by removing the first mask layer.

The first mask layer may include a photosensitive emulsion.

The second mask layer may be made of a film and attached on the first mask layer.

The second mask layer may be made of a non-photosensitive material.

At least a portion of the second thickness of the second mask layer may be embedded in the first mask layer.

The second mask layer may include a photosensitive emulsion.

A sum of the first thickness and the second thickness may be 30 μm or more.

The first mask layer and the second mask layer may be integrally formed without an interface.

The mesh may be a fiber mesh or a metal mesh.

An inner boundary of the opening may correspond to the boundary of the second mask layer.

According to one or more embodiments, a manufacturing method of a screen mask includes forming a first emulsion layer by applying a photosensitive emulsion to an upper surface of a mesh fixed to a mask frame, forming a second emulsion layer by applying a photosensitive emulsion to a lower surface of the mesh, attaching a second mask layer in a form of a film on the first emulsion layer, and arranging an exposure mask on the second mask layer, exposing the first emulsion layer and the second emulsion layer to a light through the mask, and developing the first emulsion layer and the second emulsion layer to form openings in the first emulsion layer and the second emulsion layer.

The manufacturing method of a screen mask may further include forming a third emulsion layer by applying a photosensitive emulsion to a lower surface of the second emulsion layer after the attaching of the second mask layer and before the forming of the openings.

The manufacturing method of a screen mask may further include forming a fourth emulsion layer by applying a photosensitive emulsion to a lower surface of the third emulsion layer after the forming of the third emulsion layer and before the forming of the openings.

At least a portion of a thickness of the second mask layer may be embedded in the first emulsion layer.

The second mask layer may be made of a non-photosensitive material.

The second mask layer may be used as a self-aligned exposure mask in the forming of the openings.

In the forming of the first emulsion layer and the forming of the second emulsion layer, the photosensitive emulsion may fill a space between the mesh, and the mesh may be embedded in the first emulsion layer and the second emulsion layer.

According to embodiments, an opening through which ink passes through the screen mask and printing is performed may be disposed in areas formed by a thin emulsion, thereby preventing or substantially preventing uneven printing due to irregular ink residue on the emulsion wall forming the opening, and a part made of a thick or dense material is disposed in a part corresponding to a screen where printing is not performed, thereby preventing or substantially preventing ink leakage and printing defects.

### BRIEF DESCRIPTION OF THE DRAWINGS

FIG. 1 is a layout diagram of a screen mask according to an embodiment.

FIG. 2 is a cross-sectional view taken along the line II-II of FIG. 1.

FIG. 3 is a layout view of a cover glass having a bezel part printed using a screen mask according to an embodiment.

FIGS. 4 and 5 are cross-sectional views of a screen mask according to some embodiments.

FIGS. 6 to 12 are cross-sectional views showing a manufacturing method of a screen mask according to an embodiment.

### DETAILED DESCRIPTION

The present disclosure will be described in further detail herein with reference to the accompanying drawings, in which some embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

In addition, sizes and thicknesses of components in the drawings may be arbitrarily illustrated for convenience of explanation, and the following embodiments are not limited thereto. In the drawings, the thickness of layers, films, panels, regions, etc., may be exaggerated for clarity. In the drawings, the thickness of some layers and regions may be exaggerated for ease of description.

It is to be understood that when an element, such as a layer, film, region, or substrate, is referred to as being “on” another element, it may be directly on the other element, or one or more intervening elements may also be present. In contrast, when an element is referred to as being “directly on” another element, there are no intervening elements present. Further, when an element is referred to as being “on” or “above” a reference element, it may be positioned above or below the reference element, and may not necessarily be referred to as being positioned “on” or “above” in a direction opposite to gravity.

In addition, unless explicitly stated to the contrary, the words “comprise,” “include,” and variations, such as “comprises,” “comprising,” “includes,” and “including,” are to be understood to imply the inclusion of stated elements but not the exclusion of any other elements.

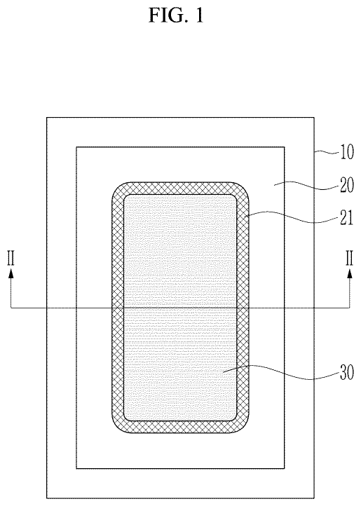

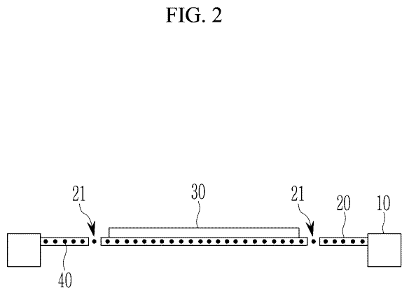

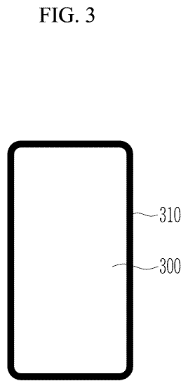

FIG. 1 is a layout diagram of a screen mask according to an embodiment; FIG. 2 is a cross-sectional view taken along the line II-II of FIG. 1; and FIG. 3 is a layout view of a cover glass having a bezel part printed using a screen mask according to an embodiment.

Referring to FIGS. 1 and 2, a screen mask according to an embodiment includes a mask frame 10, a mesh 40 fixed to the mask frame 10, a first mask layer 20 coated on the mesh 40, and a second mask layer 30 covering a region (e.g., a predetermined region) on the first mask layer 20.

The mask frame 10 may be made of any of various materials, such as any of plastic, metal, and wood, and may be maintained taut while holding the mesh 40.

In an embodiment, the mesh 40 may be a fiber mesh made of polyester or a metal mesh made of a metal, such as stainless steel.

In an embodiment, the first mask layer 20 is a layer formed by coating upper and lower surfaces of the mesh 40 with a liquid photosensitive emulsion, and may have a thickness of 10 to 20 μm. The first mask layer 20 may have an opening 21 through which ink may pass, and part of the mesh 40 may be exposed through the opening 21.

The second mask layer 30 may be a layer formed by coating a liquid emulsion on the first mask layer 20 or attaching a film. Like the first mask layer 20, the second mask layer 30 may be made of a photosensitive emulsion or may be made of a non-photosensitive material. In an embodiment, the second mask layer 30 is made of a same material as the first mask layer 20, and a total thickness of the part of the first mask layer 20 covered with the second mask layer 30 and the second mask layer 30 may be 30 μm or more. In an embodiment, the second mask layer 30 may be made of a denser material than the first mask layer 20, and, in this case, a total thickness of the first mask layer 20 and the second mask layer 30 may be less than 30 μm.

In FIG. 2, the second mask layer 30 is shown as being disposed on the first mask layer 20, but depending on an embodiment, the second mask layer 30 may be partially or entirely embedded on the first mask layer 20. That is, at least a portion of the thickness of the second mask layer 30 may be immersed in the first mask layer 20.

When screen printing is performed using a screen mask of the above structure, a bezel part 310 of a cover glass 300 may be printed, as shown in FIG. 3. That is, ink may be printed on the cover glass 300 through the opening 21 of the first mask layer 20 to form the bezel part 310. At this time, the second mask layer 30 is disposed on the central part of the cover glass 300, which serves as the screen, to reliably block ink, and the opening 21 is disposed in the first mask layer 20, which has a thin thickness, to prevent or substantially prevent the ink from remaining irregularly on the emulsion wall forming the opening, causing uneven printing.

The screen mask according to embodiments may be used in various processes using screen printing, such as semiconductor chip manufacturing and solar cell manufacturing, as well as the manufacturing of the cover glass of the display device.

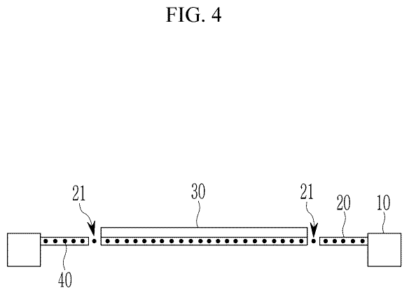

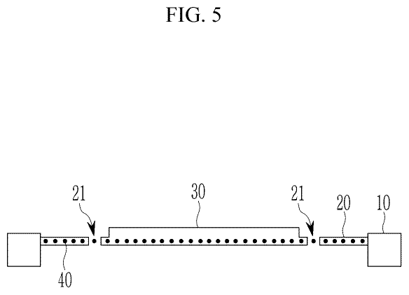

FIGS. 4 and 5 are cross-sectional views of a screen mask according to some embodiments.

The embodiment of FIG. 4 is different from the embodiment of FIG. 2 in that an inner boundary of the opening 21 corresponds to, or matches, a boundary of the second mask layer 30. If the second mask layer 30 is formed of a non-photosensitive material and the second mask layer 30 is used as a self-aligned photomask, the inner boundary of the opening 21 may easily be matched with the boundary of the second mask layer 30.

The embodiment of FIG. 5 is a case in which the first mask layer 20 and the second mask layer 30 are formed integrally without a distinct interface. In an embodiment, this structure may be obtained by coating the first mask layer 20 and the second mask layer 30 with a same material.

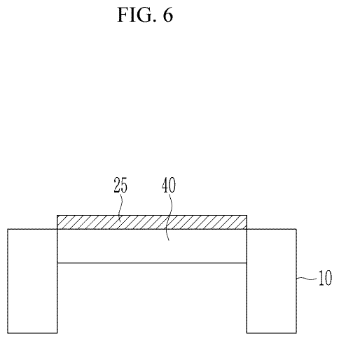

FIGS. 6 to 12 are cross-sectional views showing a manufacturing method of a screen mask according to an embodiment. In FIGS. 6 to 9, the mesh 40 is simply shown as one layer.

First, referring to FIG. 6, a photosensitive emulsion is applied to an upper surface of the mesh 40 fixed to the mask frame 10 to form a first emulsion layer 25. In the drawing, the first emulsion layer 25 is shown as a separate layer on the mesh 40, but, in an embodiment, some or all of the mesh 40 may be embedded in the first emulsion layer 25. That is, the applied photosensitive emulsion may fill all or part of the space between the mesh 40 to form the first emulsion layer 25.

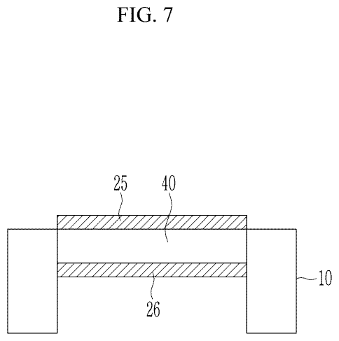

Next, referring to FIG. 7, a photosensitive emulsion is applied to a lower surface of the mesh 40 to form a second emulsion layer 26. In the drawing, the second emulsion layer 26 is shown as forming a separate layer below the mesh 40, but the structure may be such that part of the mesh 40 is embedded in the second emulsion layer 26, and the first emulsion layer 25 and the second emulsion layer 26 meet to form a layer without a separating interface, with the mesh 40 embedded therein.

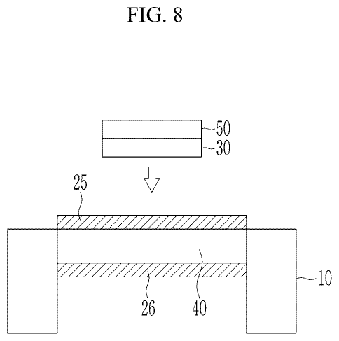

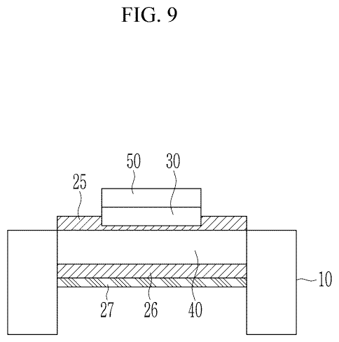

Next, referring to FIG. 8, in an embodiment, the second mask layer 30 in the form of a film attached to a support film 50 is attached to the first emulsion layer 25. At this time, as shown in FIG. 9, at least a portion of a thickness of the second mask layer 30 may be embedded in the first emulsion layer 25.

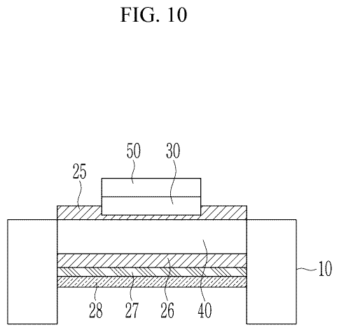

Next, referring to FIGS. 9 and 10, a photosensitive emulsion may be applied to a lower surface of the second emulsion layer 26 to additionally form a third emulsion layer 27 and a fourth emulsion layer 28. The third emulsion layer 27 and the fourth emulsion layer 28 may be layers for flattening; however, at least one of the third emulsion layer 27 and the fourth emulsion layer 28 may be omitted. The first emulsion layer 25, the second emulsion layer 26, the third emulsion layer 27, and the fourth emulsion layer 28 may form the first mask layer 20 shown in FIGS. 1, 4, and 5.

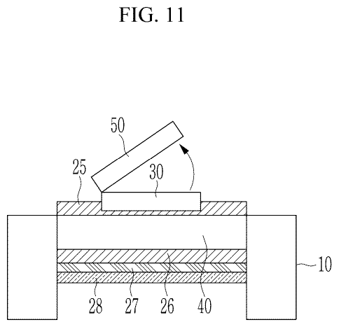

Next, referring to FIG. 11, the support film 50 is removed from the second mask layer 30.

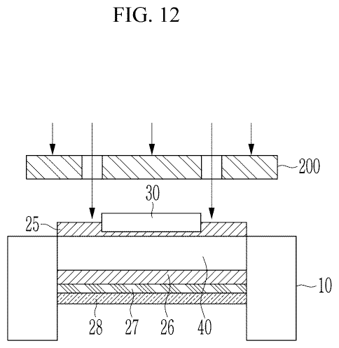

Next, referring to FIG. 12, an exposure mask 200 may be disposed on the screen mask, and then the first emulsion layer 25, the second emulsion layer 26, the third emulsion layer 27, and the fourth emulsion layer 28 may be exposed to a light through the exposure mask 200 and developed to form the opening 21 in the first mask layer 20, as shown in FIGS. 1, 4, and 5. At this time, in an embodiment, when the second mask layer 30 is not a photosensitive material, if the second mask layer 30 is used as a self-aligned exposure mask, as shown in FIG. 4, the inner boundary of the opening 21 and the second mask layer 30 may easily match the boundary.

While some embodiments of the present disclosure have been described herein, it is to be understood that the disclosure is not limited to the disclosed embodiments, but, on the contrary, is intended to cover various modifications and equivalent arrangements included within the spirit and scope of the appended claims.

What is claimed is:

1. A screen mask comprising:
a mesh;
a first mask layer having a first thickness and located in a first region of the mesh; and
a second mask layer having a second thickness and located in a second region of the mesh,
wherein the first mask layer has an opening adjacent to a boundary of the second mask layer.

2. The screen mask of claim 1, wherein the first mask layer comprises a photosensitive emulsion.

3. The screen mask of claim 2, wherein the second mask layer is made of a film and attached to the first mask layer.

4. The screen mask of claim 3, wherein the second mask layer is made of a non-photosensitive material.

5. The screen mask of claim 3, wherein at least a portion of the second thickness of the second mask layer is embedded in the first mask layer.

6. The screen mask of claim 3, wherein the second mask layer comprises a photosensitive emulsion.

7. The screen mask of claim 6, wherein a sum of the first thickness and the second thickness is 30 μm or more.

8. The screen mask of claim 7, wherein the first mask layer and the second mask layer are integrally formed without an interface.

9. The screen mask of claim 1, wherein the mesh is a fiber mesh or a metal mesh.

10. The screen mask of claim 1, wherein an inner boundary of the opening corresponds to the boundary of the second mask layer.

11. The screen mask of claim 10, wherein the first mask layer comprises a photosensitive emulsion.

12. The screen mask of claim 11, wherein the second mask layer is made of a non-photosensitive material.

13. The screen mask of claim 12, wherein the second mask layer is made of a film and attached to the first mask layer.

14. A manufacturing method of a screen mask, the manufacturing method comprising:
forming a first emulsion layer by applying a photosensitive emulsion to an upper surface of a mesh fixed to a mask frame;
forming a second emulsion layer by applying a photosensitive emulsion to a lower surface of the mesh;
attaching a second mask layer in a form of a film on the first emulsion layer; and
arranging an exposure mask on the second mask layer, exposing the first emulsion layer and the second emulsion layer to a light through the mask, and developing the first emulsion layer and the second emulsion layer to form openings in the first emulsion layer and the second emulsion layer.

15. The manufacturing method of a screen mask of claim 14, further comprising forming a third emulsion layer by applying a photosensitive emulsion to a lower surface of the second emulsion layer after the attaching of the second mask layer and before the forming of the openings.

16. The manufacturing method of a screen mask of claim 15, further comprising forming a fourth emulsion layer by applying a photosensitive emulsion to a lower surface of the third emulsion layer after the forming of the third emulsion layer and before the forming of the openings.

17. The manufacturing method of a screen mask of claim 14, wherein at least a portion of a thickness of the second mask layer is embedded in the first emulsion layer.

18. The manufacturing method of a screen mask of claim 17, wherein the second mask layer is made of a non-photosensitive material.

19. The manufacturing method of a screen mask of claim 18, wherein the second mask layer is used as a self-aligned exposure mask in the forming of the openings.

20. The manufacturing method of a screen mask of claim 14, wherein, in the forming of the first emulsion layer and the forming of the second emulsion layer, the photosensitive emulsion fills a space between the mesh, and the mesh is embedded in the first emulsion layer and the second emulsion layer.
